(19) United States
(12) Patent Application Publication
(10) Pub. No.: US 2019/0089298 A1
(43) Pub. Date: Mar. 21, 2019

(54) PHOTOVOLTAIC THIN FILM SOLID STATE BATTERY

(71) Applicant: United States of America as represented by the Administrator of NASA, Washington, DC (US)

(72) Inventor: ELEANYA E. ONUMA, GREENBELT, MD (US)

(21) Appl. No.: 15/710,197

(22) Filed: Sep. 20, 2017

(51) Int. Cl. H02S 40/38; H01L 31/0224; H01L 31/05

(52) U.S. Cl. CPC H02S 40/38; H01L 31/05; H01L 31/022425

(57) ABSTRACT

A thin film solar cell battery package may include a solar cell comprising a front side facing a light source and a back side, and a substrate material attached to the back side of the solar cell. The substrate material is sandwiched between the solar and one or more thin film batteries to physically and electrically isolate or connect the solar cell from the one or more thin film batteries.

### STATEMENT OF FEDERAL RIGHTS

The invention described herein was made by employees of the United States Government and may be manufactured and used by or for the Government for Government purposes without the payment of any royalties thereon or therefore.

### FIELD

The present invention generally relates to a battery, and more specifically, solar cell battery technology.

### BACKGROUND

Solar cells convert sunlight to electricity, which fluctuate with the intensity of sunlight. For more reliable applications, energy captured from the solar cells are sometimes stored in batteries for later use in the absence of sunlight. These two essential components (i.e., the solar cell and the battery) of a solar powered system typically have separate allocation for mass and size. The separation of these two essential components in space limited applications, such as CubeSats, is not desirable and leaves little room for additional science hardware in the CubeSat. Current solar powered system architecture involves storing the energy harvested by the solar cells located on the surface of the CubeS at in bulky lithium ion batteries stowed within a compartment of the CubeSat.

Thus, an alternative battery technology may be more beneficial.

### SUMMARY

Certain embodiments of the present invention may provide solutions to the problems and needs in the art that have not yet been fully identified, appreciated, or solved by conventional battery technologies for CubeSat. For example, some embodiments pertain to thin film solid state battery, and in certain embodiments, to a photovoltaic lithium ion battery.

In an embodiment, an apparatus may include a substrate material sandwiched between a solar cell and one or more thin film solid state batteries. The substrate material is configured to physically and electrically isolate the solar cell from the one or more batteries.

### BRIEF DESCRIPTION OF THE DRAWINGS

In order that the advantages of certain embodiments of the invention will be readily understood, a more particular description of the invention briefly described above will be rendered by reference to specific embodiments that are illustrated in the appended drawings. While it should be understood that these drawings depict only typical embodiments of the invention and are not therefore to be considered to be limiting of its scope, the invention will be described and explained with additional specificity and detail through the use of the accompanying drawings, in which:

FIG. 1 is a block diagram illustrating a battery configuration, according to an embodiment of the present invention.

FIG. 2 is a block diagram illustrating a battery stack configuration, according to an embodiment of the present invention.

### DETAILED DESCRIPTION OF THE EMBODIMENTS

Some embodiments generally pertain to battery technology within a SmallSat and/or CubeSat. Although the embodiments are not limited to SmallSat and/or CubeSat technologies, the term “CubeSat” will be used below for purposes of explanation. In certain embodiments, a battery, such as a solid state thin film lithium ion battery, may be integrated with a solar cell. This integration combines the battery and the solar cell into a small package no greater than the surface area of the solar cell, for example.

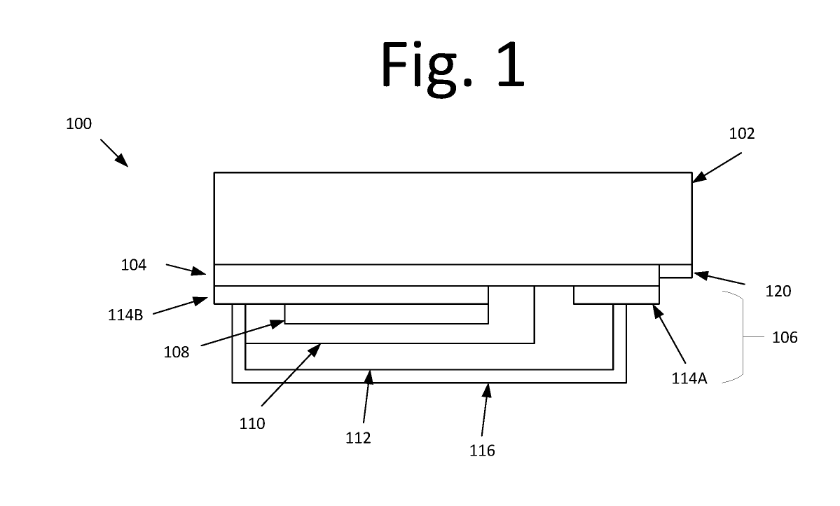

FIG. 1 is a block diagram illustrating solar cell-battery configuration 100, according to an embodiment of the present invention. In an embodiment, solar cell 102 has a front side and a back side. The front side of solar cell 102 faces a light source, such as the sun, and the back side is configured to integrate battery 106. Battery 106 may include two terminals—cathode material 108 and anode material 112. Battery 106 may also include a thin film solid state electrolyte 110, an anode current collector 114A, cathode current collector 114B, and a protective coating 116.

In some embodiments, the substrate material 104, which may be a few nanometers or microns thick, is deposited or grown on the back side of solar cell 102, sandwiching the substrate material 104 between solar cell 102 and battery 106. In one embodiment, substrate material 104 may be composed of dielectric material. However, it should be appreciated that the embodiments are not limited to dielectric material. Continuing with the above, by depositing substrate material 104 in this matter, solar cell 102 and battery 106 are electrically and physically isolated from each other. Put simply, an insulated barrier is formed between positive terminal 120 of the solar cell and current collectors 114 A, 114B. Although not shown in FIG. 1, solar cell 102 may include a negative terminal in some embodiments.

Separated by solid state electrolyte 110 and anode material 112, anode current collector 114A and cathode current collector 114B are deposited on substrate material 104. This configuration prevents physical contact and shorting between anode material 112 and cathode material 108 while allowing the transport of lithium ions through solid state electrolyte 110.

A thin layer of cathode material 108, such as lithium manganese oxide, is deposited on cathode current collector 114B. Depending on the temperature properties of solar cell 102, various thin film disposition techniques may be used. This way, physical or chemical vapor deposition techniques, such as Atomic Layer Deposition, allows for very fine assembly of thin film materials.

Solid state electrolyte 110 surrounds cathode material 108. By surrounding cathode material 108, solid state electrolyte 110 may be deposited onto a portion of cathode current collector 114B and a portion of substrate material 104. This may form a barrier between cathode material 108 and anode material 112. Anode material 112 also makes contact to substrate material 104 and anode current collector 114A.

Finally, a protective coating 116 may surround battery 106, essentially surrounding cathode material 108, solid state electrolyte 110, and anode material 112, and leaving a portion of anode current collector 114A and cathode current collector 114B exposed as terminals. The exposed terminals and current collectors in this embodiment is used as connection points for external circuits

This embodiment may provide a terminal for cathode material 108 and a terminal for anode material 112, and a positive terminal 120 and a negative terminal (not shown) for solar cell 102. An external circuit may be used to charge battery 106, or in some embodiments, control charge and discharge of battery 106.

However, in other embodiments, rather than using an electrically insulated substrate material 104, a semiconductor substrate with thin film electronics (e.g., thin film transistors, diode, or thin film circuits) may be used. These thin film electronic circuits may include a thin film power management circuitry for the photovoltaic thin film lithium ion battery configuration. Thin film sensors or detectors as well as thin film antenna or antenna array may also be deposited on this substrate.

In these embodiments, battery 106 may be built upon this layer. In other words, the semiconductor substrate is sandwiched between solar cell 102 and battery 106. The function of the sandwiched thin film electronic circuits may include power regulation and distribution of power between the solar cell and thin film battery or external circuitry.

In some additional embodiments, the thin film electronics may be built after battery 106. With this embodiment, thin film electronics connected to battery 106 may control charging of battery 106, and may wirelessly transfer power by way of converting direct current (DC) power to alternating current (AC) power and transmitting the AC power through an embedded antenna. In some embodiments, the battery and solar cell terminals may be fully encapsulated by a protective layer 116 when used in wireless applications

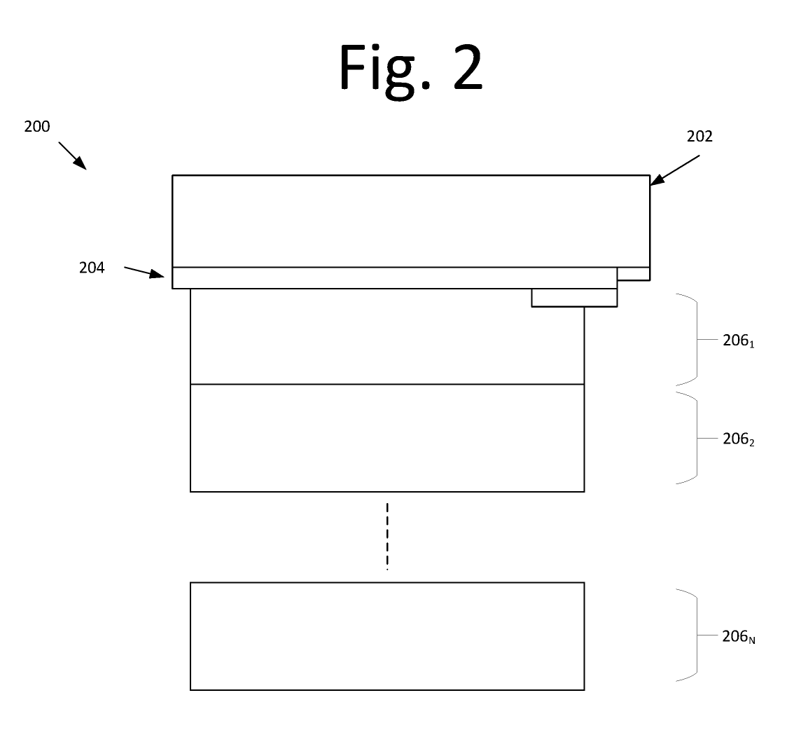

In certain embodiments, the back side of solar cell may include a series of batteries. See, for example, FIG. 2, which is a block diagram illustrating a solar cell-battery stack 200 configuration, according to an embodiment of the present invention. In this embodiment, attached to the back side of solar cell 202 may be a series of batteries 206₁ . . . 206_{N}. Regardless of the number of batteries, one of the batteries may be the primary battery with the remaining being the backup batteries. In other embodiments, all but one may be batteries that are in use with one of the batteries being the backup battery. Certain embodiments also allow several visible connection point or terminals for each or some batteries within the stack. The exposed terminals may be connected to an external circuit as needed.

In this embodiment, substrate material 204 is sandwiched between battery 206₁ and solar cell 202 to physically and electrically isolate solar cell 202 and the battery stack (e.g., battery 206₁ . . . 206_{N}). In other embodiments, thin film electronic circuits embedded in the semiconductor substrate material may be sandwiched between each battery 206₁ . . . 206_{N}. For example, each thin film electronic circuit in each substrate may be designed to perform different unique functions with a shared or sole battery source. This embodiment can also support wireless charging of all thin film battery within the stack. In some other embodiments, the thin film electronic circuit, such as thin film antennas embedded in the substrate material, may be placed underneath battery 206_{N}.

For space applications, some embodiments combine solid thin film lithium ion batteries with multi-junction solar cells to form a single device that provides better mechanical structure for the solar cell. This configuration may allow for light weight high power density, multilayer battery stack.

Also with the emerging aerosol jet printing technology, thin film circuits printed on this single device enables wireless solar battery technology. For example, the thin film printed circuit may convert the battery stored DC power to AC power, which is then transfer to another device via induction. This will effectively eliminate the need for a wall plugged-battery charger. For example, the photovoltaic lithium ion battery may be charged in doors with sufficient room light.

Not only is this configuration beneficial to the aerospace industry, but is also beneficial for commercial and residential buildings that employ solar panels. For example, a smart photovoltaic battery may be integrated into specially designed roofing tiles for solar power generation. For wireless power transfer in commercial or residential buildings, an array of photovoltaic batteries with appropriate embedded thin film electronics and phased array antennas may harvest, convert and wirelessly transfer power to a specific device or devices within the building.

The application of the battery may extend into flexible electronics industry as well. For example, when paired with flexible solar cell, the battery may be used for wearable electronics or monitors.

For compatibility with existing technologies that utilize the traditional cylindrical batteries, the battery may be integrated into flexible solar cells that are rolled up and confined in a cylindrical shell with two terminals when in use. To charge the battery, the user pulls a tab on the cylinder that unravels the battery like a scroll. A retraction mechanism could be designed into the device to retract the battery when fully charged.

The application also extends to visual displays such as smartphones, TVs, or desktop monitors. When integrated with a transparent AMOLED display the photovoltaic battery may power electronic devices using light sources emitted from the transparent screen as well as the ambient room light. Since the transparent AMOLED display emits light as well as allows light to pass through it, a big energy saving can be achieved. Such a display would have an extended battery life as well.

Lastly, because solar cells need direct access to sunlight for efficient performance we've been limited to two dimensional (2D) solar panels that can take up big real estate. Since this embodiment also allows stacking of multilayers solid state thin film lithium ion batteries, some embodiments may allow for stacking of photovoltaic batteries in a cube formation for applications with constrained real estate. In such an embodiment, power is transferred from one photovoltaic battery to another within the cube using highly efficient embedded light emitting diodes located at the end of each multi-layer photovoltaic battery. Where one of each of the multilayer batteries may act as a power source for highly efficient embedded light emitting diodes.

It will be readily understood that the components of various embodiments of the present invention, as generally described and illustrated in the figures herein, may be arranged and designed in a wide variety of different configurations. Thus, the detailed description of the embodiments of the present invention, as represented in the attached figures, is not intended to limit the scope of the invention as claimed, but is merely representative of selected embodiments of the invention.

The features, structures, or characteristics of the invention described throughout this specification may be combined in any suitable manner in one or more embodiments. For example, reference throughout this specification to “certain embodiments,” “some embodiments,” or similar language means that a particular feature, structure, or characteristic described in connection with the embodiment is included in at least one embodiment of the present invention. Thus, appearances of the phrases “in certain embodiments,” “in some embodiment,” “in other embodiments,” or similar language throughout this specification do not necessarily all refer to the same group of embodiments and the described features, structures, or characteristics may be combined in any suitable manner in one or more embodiments.

It should be noted that reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention. In order to determine the metes and bounds of the invention, therefore, reference should be made to the appended claims.

1. An apparatus, comprising:
a solar cell comprising a front side facing a light source and a back side;
a substrate material attached to the back side of the solar cell, wherein
the substrate material is sandwiched between the solar and one or more thin film batteries to physically and electrically isolate or connect the solar cell from the one or more thin film batteries.

2. The apparatus of claim 1, wherein the substrate material comprises a thin film dielectric material configured to form an insulated barrier between a positive terminal of the solar cell and a current collector of the one or more thin film batteries.

3. The apparatus of claim 1, wherein the substrate material comprises a semiconductor substrate configured to regulate and distribute power between the solar cell and the one or more batteries.

4. The apparatus of claim 3, wherein the semiconductor substrates is further configured to wirelessly transfer power by converting direct current power to alternating current power, followed by transmitting the AC power through an embedded antenna.

5. The apparatus of claim 1, further comprises:
an anode current collector and a cathode current collector is deposited on the substrate material to prevent physical contact and shorting between anode material and cathode material.

6. The apparatus of claim 5, wherein the anode current collector and the cathode current collector are configured to allow transport of lithium ions though a thin film solid state electrolyte.

7. The apparatus of claim 1, further comprising:
a cathode material deposited on a cathode current collector; and
a solid state electrolyte surrounding the cathode material and deposited onto a portion of the cathode current collector and a portion of the substrate material to form a barrier between the cathode material and anode material.

8. The apparatus of claim 7, wherein the anode material is in contact with the substrate material and the anode current collector.

9. The apparatus of claim 8, further comprising:
a protective coating surrounds the one or more batteries, leaving a portion of the anode current collector and the cathode current collector exposed as terminals, wherein
the exposed terminals act as connections points for external circuits.

10. A thin film solar cell battery for a CubeSat, comprising:
a solar cell comprising a front side facing a light source and a back side;
a substrate material attached to the back side of the solar cell, wherein
the substrate material is sandwiched between the solar and a thin film battery to physically and electrically isolate or connect the solar cell from the thin film battery.

11. The thin film solar cell battery of claim 10, wherein the substrate material comprises a thin film dielectric material configured to form an insulated barrier between a positive terminal of the solar cell and a current collector of the thin film battery.

12. The thin film solar cell battery of claim 10, wherein the substrate material comprises a semiconductor substrate configured to regulate and distribute power between the solar cell and the thin film battery.

13. The thin film solar cell battery of claim 12, wherein the semiconductor substrates is further configured to wirelessly transfer power by converting direct current power to alternating current power, followed by transmitting the AC power through an embedded antenna.

14. The thin film solar cell battery of claim 10, further comprises:
an anode current collector and a cathode current collector is deposited on the substrate material to prevent physical contact and shorting between anode material and cathode material.

15. The thin film solar cell battery of claim 14, wherein the anode current collector and the cathode current collector are configured to allow transport of lithium ions though a thin film solid state electrolyte.

16. The thin film solar cell battery of claim 10, further comprising:
a cathode material deposited on a cathode current collector; and
a solid state electrolyte surrounding the cathode material and deposited onto a portion of the cathode current collector and a portion of the substrate material to form a barrier between the cathode material and anode material.

17. The thin film solar cell battery of claim 16, wherein the anode material is in contact with the substrate material and the anode current collector.

18. The thin film solar cell battery of claim 17, further comprising:
a protective coating surrounds the thin film battery, leaving a portion of the anode current collector and the cathode current collector exposed as terminals, wherein
the exposed terminals act as connections points for external circuits.

19. An apparatus, comprising:
a substrate material sandwiched between a solar cell and one or more thin film solid state batteries, wherein
the substrate material is configured to physically and electrically isolate the solar cell from the one or more batteries.
